(19) United States
(12) Patent Application Publication
(10) Pub. No.: US 2002/0074590 A1
(43) Pub. Date: Jun. 20, 2002

(54) Non-volatile flash memory cell with asymmetric threshold voltage

(75) Inventors: Fu-Cheng Jong, Tainan City (TW); Kent Kuohua Chang, Taipei City (TW); Chia-Hsing Chen, Hsin-Chu (TW)

Correspondence Address: LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/739,213

(22) Filed: Dec. 19, 2000

(51) Int. Cl. H01L 29/76

(52) U.S. Cl. 257/314

(57) ABSTRACT

A non-volatile flash memory cell with an asymmetric threshold voltage comprises a channel region, a doping region, a floating gate, and a control gate. The channel region is located in a surface of a substrate and between a source and a drain in the substrate. The doping region is located in one side of the channel region near the source and a plurality of a first dopants and a plurality of a second dopants are doped in the doping region and the substrate with the same conductivity. The control gate is located over the channel region and insulated to the channel region. The floating gate is located between the channel region and the control gate, and is simultaneously insulated to each other. The present flash memory cell still can extend to divide the channel region to a first channel region near the source and a second channel region near the drain without using the doping region. Moreover, a threshold voltage of the first channel region is larger than a threshold voltage of the second channel region.

### BACKGROUND OF THE INVENTION

1. Field of the Invention

The present invention generally relates to a non-volatile flash memory cell with an asymmetric threshold voltage, and more particularly relates to a non-volatile flash memory cell which raises a threshold voltage of a portion of a channel region to prevent the abnormal erase.

2. Description of the Prior Art

Flash memory have been broadly applied to replicatively access data but not disappear as power breaking down, such as the film of digital camera or the basic input-output system of a mother board, because flash memory has the advantages of electrically erasable and programmable mechanisms. Flash memory can simultaneously proceed the erase and the program mechanisms to all flash memory cells in the whole memory's array. Accordingly, how to advance the performance and reduce the cost of flash memory becomes an important subject.

Referring to FIG. 1A, a common structure of a flash memory cell is a stacked structure which basically comprises a source 11, a drain 12, a floating gate 13, and a control gate 14. The source 11, the drain 12, and the control gate 14 are connected with different power sources to control the programming process, the reading process, and the erasing process of flash memory. The floating gate 13 and the control gate 14 are surrounded by a dielectric layer 15 on a substrate 10.

In respect to a N type flash memory cell (the substrate 10 is an N type substrate), the source is grounded, and the control gate 14 and the drain 12 are put a positive voltage in a programming mechanism. Because no LDD is used, so partial electrons will diffuse into the floating gate 13 and is trapped in the floating gate 13 by the potential barrier of the surrounding dielectric layer 15. Moreover, electrons in the floating gate 13 will effect the threshold voltage of the channel region between the source 11 and the drain 12, and control the conduction of the channel region. Then, electrons in the floating gate 13 can be reputed as data which is read by the conduction of the channel region. In an erasing mechanism, the source 11 is grounded, and the control gate 14 is put a positive voltage which is lower than the drain 12. Electrons in the floating gate 13 will disappear by Fowler-Nordheim tunneling.

Obviously, referring to FIG. 1B, the performance of flash memory cell will be affected by the under erase (residual electrons in the floating gate 13) or the over erase (further bring positive charges 16 from the floating gate 13). For example, the over erase of flash memory causes not proceeding the accessing data because positive charges 16 in the floating gate 13 will result to charge neutrality or the change of the conduction of the channel region. Furthermore, the flash memory could not access any data if positive charges 16 in the floating gate 13 are so many to automatically conduct the channel region.

Besides, flash memory array often comprises many flash memory cells in actual applications, such as a bit line of a low-density high-response rate “NOR” structure. Therefore, an abnormal operation of a single flash memory cell often causes the lapse of the whole flash memory array. If the problem of abnormal erase is solved by a application of a circuit way, it must add a testing circuit in each cell which will complicate the structure of flash memory, reduce the area for flash memory array, and increase the testing time and cost.

Another way to solve this problem is to use a split gate. Referring to FIG. 1C, in this time, the channel region can divide to two parts which one is only having the control gate 17 thereon and another is both having the control gate 17 and the floating gate 17 thereon. Obviously, as shown in FIG. 1D, positive charges 18 in the floating gate 18 are accrued when the abnormal erase happens. However, there is only the channel region under the floating gate 18 could not control the conduction, and the channel region which is not under the floating gate 18 can still control by the control gate 17. In other word, the problem of the over erase can be effectively prevent and almost use a drain hot carriers injection method to feed electrons into the floating gate 18, which the efficiency is about 100 times efficiency of the source hot carriers injection method. Certainly, the type and the proceeding way of the split gate can have many varieties, as references to U.S. Pat. No. 4,639,893, U.S. Pat. No. 5,486,711, and U.S. Pat. No. 4,868,629.

Comparing FIG. 1A and FIG. 1C, the structure of flash memory cell with a split gate is more complicated than the structure of the stacked structure of flash memory cell, especially the shapes of the control gate 17 and the control gate 14 are different. However, the flash memory cell with a split gate has a higher cost in complicated processes. Further, in the antecedent of the same function of the floating gate 18 and the floating gate 13, the area of flash memory cell with a split gate is bigger because the length of the control gate 17 is longer than the length of the control gate 14.

As above discussions, conventional structures of all kinds of flash memory cell could not effectively prevent the abnormal erase, or can solve the problem but complicate the process and increase the cost. Hence, it needs to develop a new structure of flash memory cell to effectively enhance programming and erasing.

### SUMMARY OF THE INVENTION

The primary object of the invention is to provide a non-volatile flash memory cell which can effectively prevent the abnormal erase.

Another object of the invention is in an antecedent of not obviously modifying the structure of a stacked flash memory cell to prevent the abnormal erase.

The invention further comprises an object to prevent the abnormal erase in an NOR structure of an N type flash memory.

In order to achieve previous objects of the invention, a non-volatile flash memory cell with an asymmetric threshold voltage comprises a channel region, a doping region, a floating gate, and a control gate. The channel region is located in a surface of a substrate and between a source and a drain in the substrate. The doping region is located in one side of the channel region near the source and a plurality of a first dopants and a plurality of a second dopants are doped in the doping region and the substrate with the same conductivity. The control gate is located over the channel region and insulated to the channel region. The floating gate is located between the channel region and the control gate, and is simultaneously insulated to each other.

Besides, the present flash memory cell still can extend to divide the channel region to a first channel region near the source and a second channel region near the drain without using the doping region. Moreover, a threshold voltage of the first channel region is larger than a threshold voltage of the second channel region. In the other word, the key point of the present invention is using a channel region, which has a larger threshold voltage, to prevent the abnormal operation of the flash memory cell but not to prevent the abnormal erase occurring.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A is the schematic representation of the structure of a conventional stacked flash memory cell;

FIG. 1B is the schematic representation of the structure of a conventional stacked flash memory cell by the over erase;

FIG. 1C is the schematic representation of the structure of a conventional flash memory cell with a split gate;

FIG. 1D is the schematic representation of the structure of a conventional flash memory cell with a split gate by the over erase;

FIG. 2A is the schematic representation of one structure of a flash memory cell, in accordance with the present invention;

FIG. 2B is the mechanism schematic representation of the structure of a flash memory cell to prevent the abnormal erase, in accordance with the present invention; and

FIG. 2C is the schematic representation of another structure of a flash memory cell, in accordance with the present invention.

FIG. 2D is the schematic representation of another structure of a flash memory cell, in accordance with the present invention.

### DESCRIPTION OF THE PREFERRED EMBODIMENT

Aims at the drawback which the channel region under the floating gate will abnormally be conducted by the abnormal erase of the floating gate to solve. The present invention points out a key point to solve the drawback that the channel region can be divided into two parts, which one is affected and another is not affected by the abnormal erase of the floating gate, so the not affected part of the channel region can control the conduction of the whole channel region.

Obviously, conventional split gate is only to divide the channel region to two parts, wherein one part of the channel region is conducted by the abnormal erase of the floating gate, and another part of the channel region is not conducted by the abnormal erase of the floating gate. Aims at main drawbacks of a conventional flash memory with a split gate: complicated processes and big chip area. However, the distance of the gate and the substrate (the channel region) is not the point for controlling the conduction of the channel, but the threshold voltage of the channel region is the point for controlling the conduction of the channel. The present invention provides a way to section the channel region. The way is not changing the array of the control gate and the floating gate in a stacked flash memory cell, but changing the distribution of the threshold voltage of the channel region to section the channel region by asymmetric distribution of the threshold voltage.

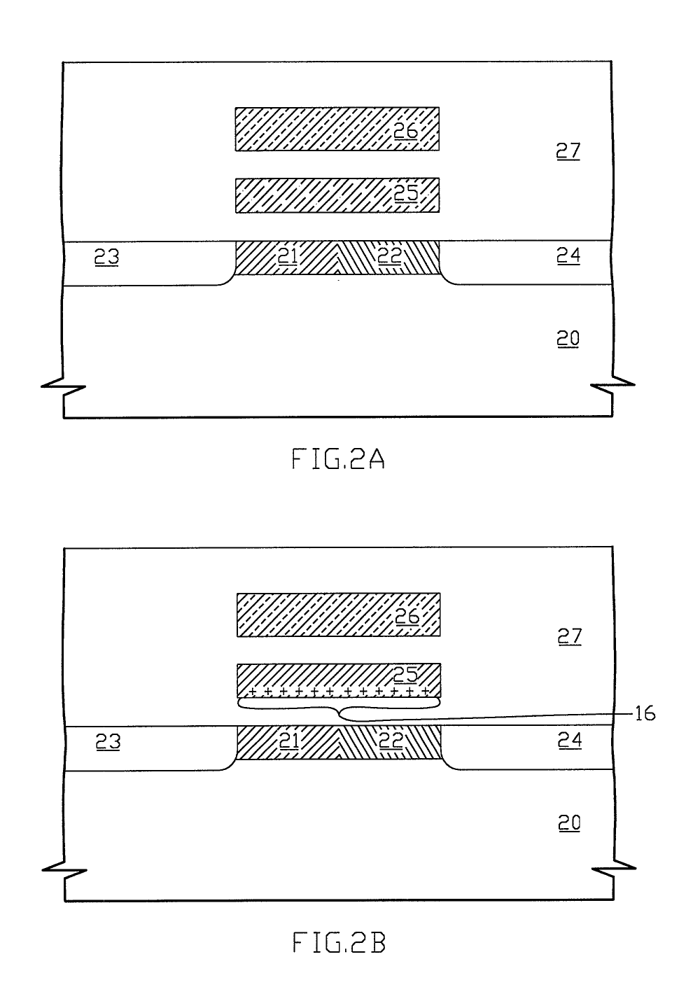

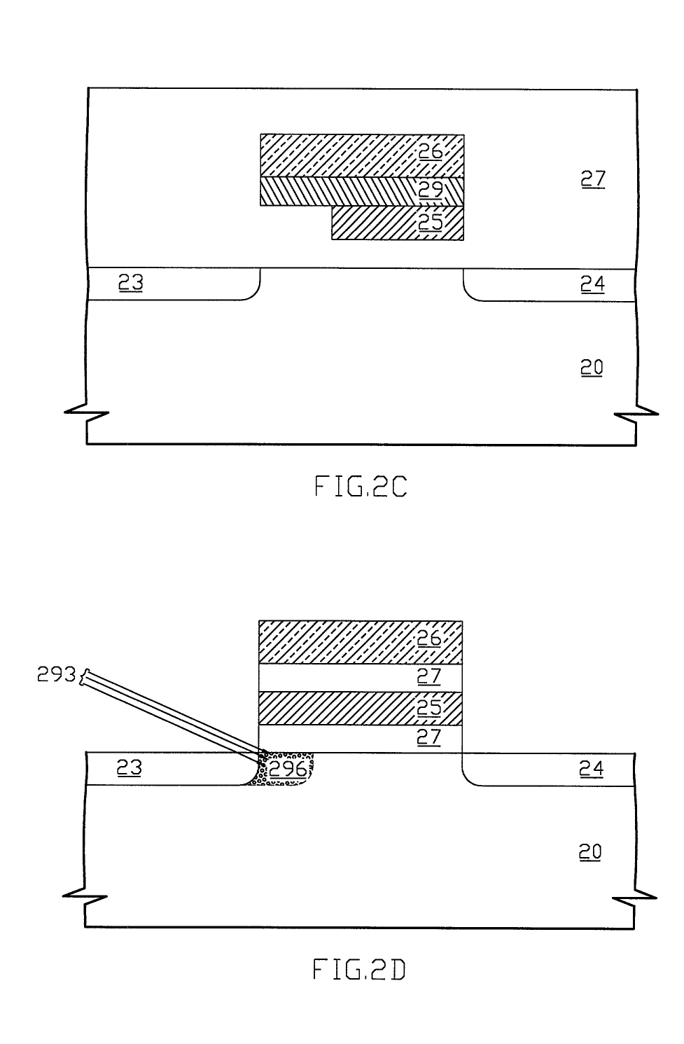

According to above idea, the present invention provides a non-volatile flash memory cell, as shown in FIG. 2A. The non-volatile flash memory cell comprises a first channel region 21, a second channel region 22, a source 23, a drain 24, a floating gate 25, and a control gate 26.

The channel region is located in a surface of the substrate 20 (such as a P type substrate) and between the source 23 and the drain 24 in the surface of the substrate 20. Herein, the channel region can be divide to a first channel region 21 near the source 23 and a second channel region 22 near the drain 24, and a threshold voltage of the first channel region is larger than a threshold voltage of the second channel region.

The control gate 26 is located over the channel region and insulated to the channel region. The floating gate 25 is located between the channel region and the control gate 26, and simultaneously insulated to each other. Certainly, the floating gate 25 and the control gate 26 are located in the dielectric layer 27, so the substrate 20, the floating gate 25, and the control gate 26 are insulated to each other with the dielectric layer 27.

Obviously, the threshold voltage of the first channel region 21 is large than the threshold voltage of the second channel region 22. Then, the depletion region near the drain 24 will extended to the source 23 and electrons (a few carriers of the P type substrate) will be injected into the floating gate 25 by a source hot carriers injection method. According as the increasing amount of electrons, the input point will near to the drain 24.

This time the threshold voltage of the first channel region 21 is larger. The control gate 26 is put on a voltage to just conduct the second channel region and the first channel region is not conducted. The first channel region 21 need a large voltage to let the first channel region 21 conduct. Hence, even the abnormal erase causes the second channel region 22 under the floating gate 25 conducted abnormally, the whole flash memory cell will not lapse except the threshold voltage of the first channel region 21 is high enough to not be conducted by the advent positive charges 28. In the other word, the performance of flash memory cell is not affected by the abnormal erase by adjusting the threshold voltage of the first channel region 21. Certainly, how large is the threshold voltage of the first channel region to prevent the influence of the abnormal erase can be obtained from data of the testing process.

Herein, the common way for adjusting the threshold voltage is using an ions implantation method to implant a plurality of impurities 293 (such as boron ions) into one side of the channel region near the source 23 to form a doping region 296 (the location of the doping region 296 can be regarded as the first channel region 21 and other part of the channel region can be regarded as the second channel region 22), as shown in FIG. 2D (herein, the dielectric layer 27 is only a portion). Impurities doped in the doping region 296 and impurities doped in the substrate 20 are in the same conductivity. Because the threshold voltage is affined to the status of the surface of the substrate 20, so a thickness of the doping region 296 is usually smaller than a thickness of the channel region (comparing to FIG. 2D and FIG. 2A). Impurities 293 are implanted into the substrate 20 by a large angle implanting technique and the implanting angle is about 20 degrees to the surface of the substrate 20.

Because the threshold voltage is in inverse proportion to a capacitance of the dielectric layer between the floating gate 25 and the substrate 20, a capacitance of the dielectric between the first channel region and the floating gate 25 can be adjusted lower than a capacitance of the dielectric layer between the second channel region and the floating gate 25. In the other word, it can adjust the threshold voltage by forming the dielectric layer, which has different capacitance distribution under the floating gate, without using different dopants to adjust the threshold voltage.

Last, when erasing the cell is needed, it only need put a positive voltage to the drain 23 and a negative voltage to the control gate 26, and then electrons in the floating gate 25 will be pushed to the drain 23 by Fowler-Nordheim tunneling.

Obviously, the present invention can effectively prevent the abnormal eras which make the flash memory cell abate. Hence, the present invention can prevent the abnormal erase of a NOR structure of flash memory. However, because the present invention only need to modify the structure of flash memory cell without additional testing circuits to test the flash memory array, the present invention can economize chips area, testing time, and reducing the cost.

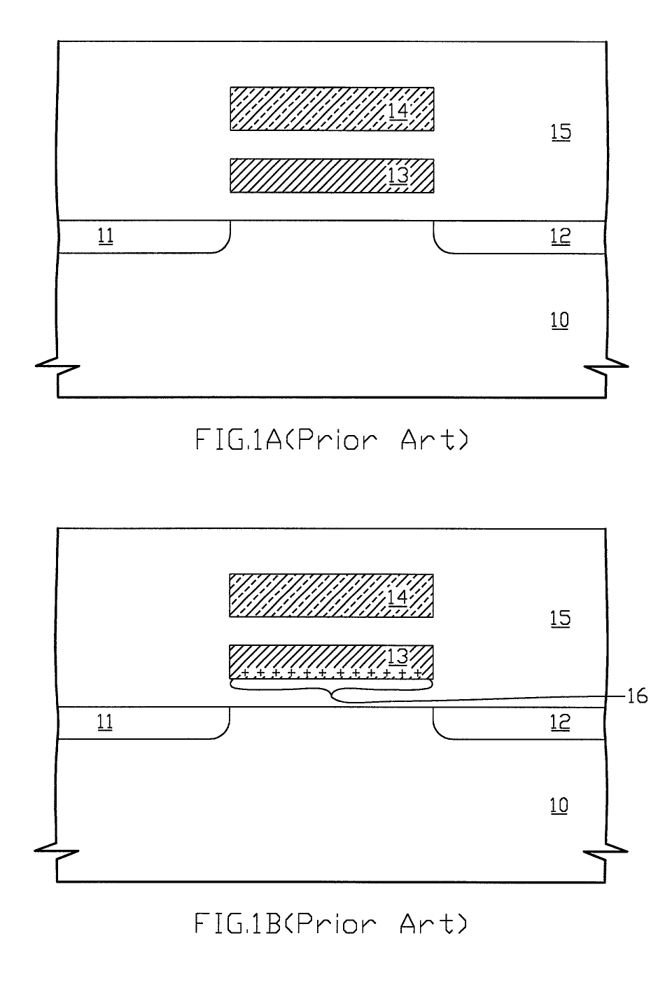

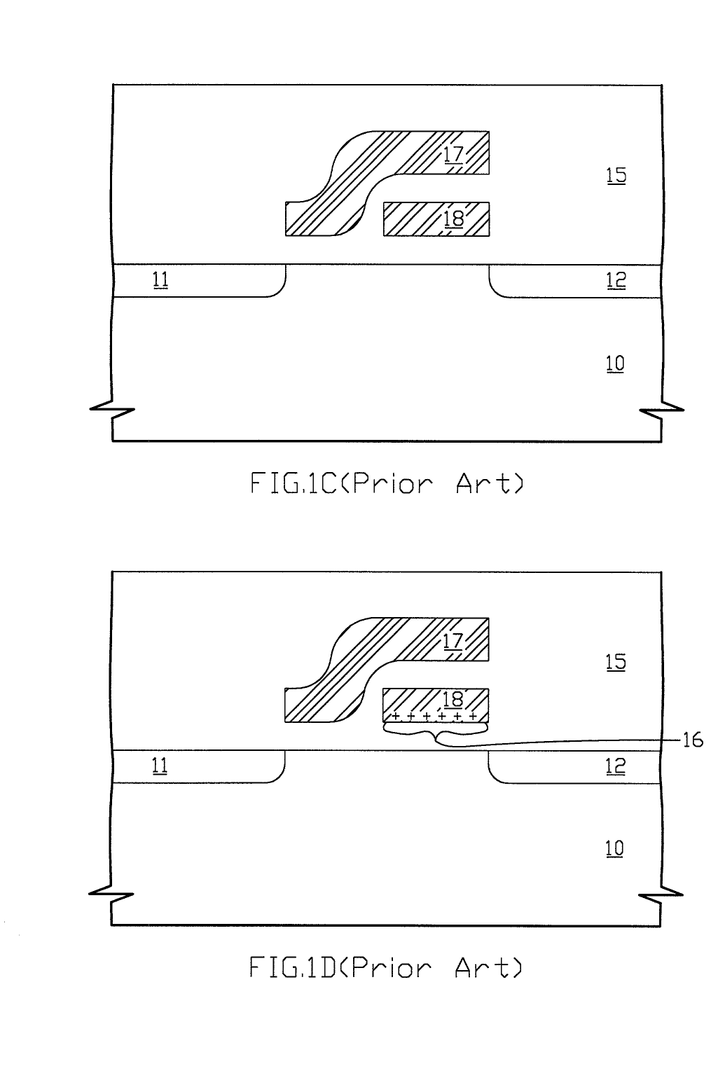

Comparing FIG. 2A, FIG. 1A, and FIG. 1C, the present invention is basically a stacked flash memory cell. The control gate 26 and the floating gate 25 are approximately parallel to each other, and a bottom of the control gate 26 is more far from the substrate 20 than a top of the floating gate 25. The shapes of the control gate 26 and the floating gate 25 are simple and can be formed by using a depositing process and an lithography process. Furthermore, the formation of the control gate 26 and the floating gate 25 is simple and do not need any processes to form the bow control gate 17 as shown in FIG. 1C. The process of the present invention is easier than the process of the conventional flash memory cell with a split gate.

Besides, although the floating gate 23 and the substrate 20 are parallel in FIG. 2A, but the present invention is not limited by it. The point of the present invention is that the threshold voltage to the channel region is not asymmetric and using the threshold voltage near one side of the source 23 prevents the abnormal conduction when the erase abnormal occurs. As regards, the array of the floating gate 25 and the control gate 26 can be adjusted.

Last, as shown in FIG. 2C, the control gate 26 and the floating gate 25 are separated with a composite dielectric layer 29 to increase the dielectric constant and the electrons in the floating gate 25. Herein, the composite dielectric layer 29 is formed by stacking three dielectric layers, which the middle layer is selected from the group: silicon nitride or silicon nitride oxide, and two surface layers is made of oxide.

Of course, it is to be understood that the invention need not be limited to these disclosed embodiments. Various modification and similar changes are still possible within the spirit of this invention. In this way, the scope of this invention should be defined by the appended claims.

What is claimed is:

1. A non-volatile flash memory cell, said memory cell comprising:
a channel region located in a surface of a substrate and between a source and a drain, wherein said source and said drain are located in said surface of said substrate;
a doping region located in one side of said channel region near said source, wherein a plurality of a first dopants doped in said doping region and a plurality of a second dopants doped in said substrate are in the same conductivity;
a control gate located over said channel region and insulated to said channel region; and
a floating gate located between said channel region and said control gate, wherein said floating gate is insulated to both said channel region and said control gate.

2. The memory cell according to claim 1, wherein said control gate and said floating gate are approximately parallel.

3. The memory cell according to claim 1, wherein a thickness of said doping region is smaller than a thickness of said channel region.

4. The memory cell according to claim 1, wherein said substrate is a P type substrate.

5. The memory cell according to claim 1, wherein said first dopants are boron ions.

6. The memory cell according to claim 1, wherein said first dopants are implanted into said channel region to form said doping region by an ions implantation method.

7. The memory cell according to claim 5, wherein said first dopants are implanted into said substrate by a large angle implanting technique.

8. The memory cell according to claim 7, wherein an angle of said dopants implanted into said substrate is about 20 degrees to said surface of said substrate.

9. The memory cell according to claim 1, wherein said control gate and said floating gate are insulated with a composite dielectric layer.

10. The memory cell according to claim 9, wherein said composite dielectric layer is formed by stacked three dielectric layers.

11. The memory cell according to claim 10, wherein a middle layer of said three dielectric layers is selected from the group consisting of silicon nitride layer and silicon nitride oxide layer.

12. The memory cell according to claim 10, wherein two surface layers of said three dielectric layers are made of oxide.

13. The memory cell according to claim 1, wherein said floating gate and said substrate are insulated wit a dielectric layer.

14. The memory cell according to claim 1, wherein a plurality of electrons are injected into said floating gate by using a drain hot carrier injection method.

15. A non-volatile flash memory cell, said memory cell comprising:
a channel region located in a surface of a substrate and between a source and a drain in said substrate, wherein said channel region can be divided into a first channel region near said source and a second channel region near said drain, and a threshold voltage of said first channel region is larger than a threshold voltage of said second channel region;
a control gate located over said channel region and insulated to said channel region; and
a floating gate located between said channel region and said control gate and insulated to both said channel region and said control gate.

16. The memory cell according to claim 15, wherein said substrate is a P type substrate.

17. The memory cell according to claim 15, wherein said channel region is implanted into a plurality of first dopants which have a same conductivity to said substrate.

18. The memory cell according to claim 17, wherein said first dopants are implanted into said channel region by an ions implantation method.

19. The memory cell according to claim 17, wherein said first dopants are implanted into said substrate by a large angle implanting technique.

20. The memory cell according to claim 15, wherein a capacitance of a dielectric layer between said first channel region and said floating gate is smaller than a capacitance of a dielectric layer between said second channel region and said floating gate.
